(19) United States
(12) Patent Application Publication
(10) Pub. No.: US 2024/0258403 A1
(43) Pub. Date: Aug. 1, 2024

(54) IN-SITU DEPOSITION OF OXIDE PASSIVATION LAYER ON III-NITRIDE BASED HEMT

(71) Applicant: University of South Carolina, Columbia, SC (US)

(72) Inventors: Iftikhar Ahmad, Irmo, SC (US); Samiul Hasan, Columbia, SC (US); Mohi Uddin Jewel, Columbia, SC (US)

(73) Assignee: University of South Carolina, Columbia, SC (US)

(21) Appl. No.: 18/520,979

(22) Filed: Nov. 28, 2023

Related U.S. Application Data
(60) Provisional application No. 63/482,348, filed on Jan. 31, 2023.

(51) Int. Cl. H01L 29/66; H01L 29/40; H01L 29/51; H01L 29/778

(52) U.S. Cl. CPC H01L 29/66462; H01L 29/408; H01L 29/517; H01L 29/7786

(57) ABSTRACT

Described herein are methods, systems, and processes for in-situ oxide dielectric deposition in the same reactor, integrating III-Nitride and III-Oxide technology using N₂ as carrier gas that results in a lower density of interface traps (charges).

### STATEMENT REGARDING FEDERALLY SPONSORED RESEARCH

This invention was made with government support under Grant Number #2124624, awarded by the NSF. The government has certain rights in the invention.

### TECHNICAL FIELD

The subject matter disclosed herein is generally directed to methods, systems, and processes for in-situ oxide dielectric deposition in the same reactor, integrating III-Nitride and III-Oxide technology using N₂ as carrier gas that results in a lower density of interface traps (charges).

### BACKGROUND

Currently, the oxide deposition for GaN/AlGaN based high electron mobility transistors is done with different deposition tools, which creates additional steps, as well as high interfacial charge density at the oxide and barrier layer interface. This multi tool dependency increases per unit cost of the devices, whereas high interfacial charges can reduce the device performance.

Accordingly, it is an object of the present disclosure to simplify the fabrication process by making it single tool dependent. In this process, the interfacial charge density is also low, compared to the multi-step process.

Citation or identification of any document in this application is not an admission that such a document is available as prior art to the present disclosure.

### SUMMARY

The above objectives are accomplished according to the present disclosure by providing in one embodiment, a method for forming a metal oxide semiconductor heterojunction field effect transistor. The method may include employing a single process step in-situ metal-organic chemical vapor phase epitaxy using nitrogen as a carrier gas to provide for vertical metal-organic chemical vapor deposition wherein at least one ultra-wide-bandgap semiconductor is deposited via metal-organic chemical vapor deposition onto at least one high-electron-mobility transistor heterostructure onto at least one sapphire substrate to form at least one in-situ metal oxide semiconductor heterojunction field effect transistor. Further, the at least one in-situ metal oxide semiconductor heterojunction field effect transistor may have a decrease in interfacial charge density for the in-situ formed metal oxide semiconductor heterojunction field effect transistor in a range of 70%-88% for a 10 nm to 30 nm oxide layer thickness as compared to an ex-situ formed metal oxide semiconductor heterojunction field effect transistor. Still further, the at least one in-situ metal oxide semiconductor heterojunction field effect transistor may have a reduction in interfacial trap density as compared an ex-situ formed metal oxide semiconductor heterojunction field effect transistor. Yet again, the at least one in-situ metal oxide semiconductor heterojunction field effect transistor may be formed to have a dielectric constant of 10.6 and bandgap of 4.9 eV. Further yet, the ultra-wide-bandgap semiconductor may comprise gallium oxide. Even further, the at least one high-electron-mobility transistor heterostructure may comprise an AlGaN/GaN-based heterostructure. Moreover, the at least one in-situ metal oxide semiconductor heterojunction field effect transistor may be formed to comprise, an upper most β-Ga₂O₃ layer above a AlGaN barrier layer above an AlN spacer layer above a GaN layer over a second AlN layer atop the at least one sapphire substrate. Even further, trimethylaluminum, ammonia, and ultra-high purity oxygen may be used as aluminum, nitrogen, and oxygen precursors. Further still, the method may be performed in a single reactor.

In a further embodiment, the disclosure provides an improved metal oxide semiconductor heterojunction field effect transistor. The transistor may include at least one uppermost β-Ga₂O₃ layer formed above a AlGaN barrier layer that is formed above an AlN spacer layer formed above a GaN layer formed over a second AlN layer formed atop at least one sapphire substrate and the metal oxide semiconductor heterojunction field effect transistor may be formed in situ in a single reactor. Still further, the in-situ metal oxide semiconductor heterojunction field effect transistor may have a decrease in interfacial charge density for the in-situ formed metal oxide semiconductor heterojunction field effect transistor in a range of 70%-88% for a 10 nm to 30 nm oxide layer thickness as compared to an ex-situ formed metal oxide semiconductor heterojunction field effect transistor. Yet again, the at least one in-situ formed metal oxide semiconductor heterojunction field effect transistor may have a reduction in interfacial trap density as compared to Ga₂O₃ grown ex-situ. Further yet, the at least one in-situ formed metal oxide semiconductor heterojunction field effect transistor may have a dielectric constant of 10.6 and bandgap of 4.9 eV. Still further, the ultra-wide-bandgap semiconductor may comprise gallium oxide. Furthermore, the at least one high-electron-mobility transistor heterostructure may comprise an AlGaN/GaN-based heterostructure. Yet again, the at least one in-situ metal oxide semiconductor heterojunction field effect transistor may have an upper most j-Ga₂O₃ layer above a AlGaN barrier layer above an AlN spacer layer above a GaN layer over a second AlN layer atop the at least one sapphire substrate. Still yet, trimethylaluminum, ammonia, and ultra-high purity oxygen may be used as aluminum, nitrogen, and oxygen precursors.

These and other aspects, objects, features, and advantages of the example embodiments will become apparent to those having ordinary skill in the art upon consideration of the following detailed description of example embodiments.

### BRIEF DESCRIPTION OF THE DRAWINGS

An understanding of the features and advantages of the present disclosure will be obtained by reference to the following detailed description that sets forth illustrative embodiments, in which the principles of the disclosure may be utilized, and the accompanying drawings of which:

FIG. 1 shows an example of an AlGaN/AlN/GaN Heterostructure.

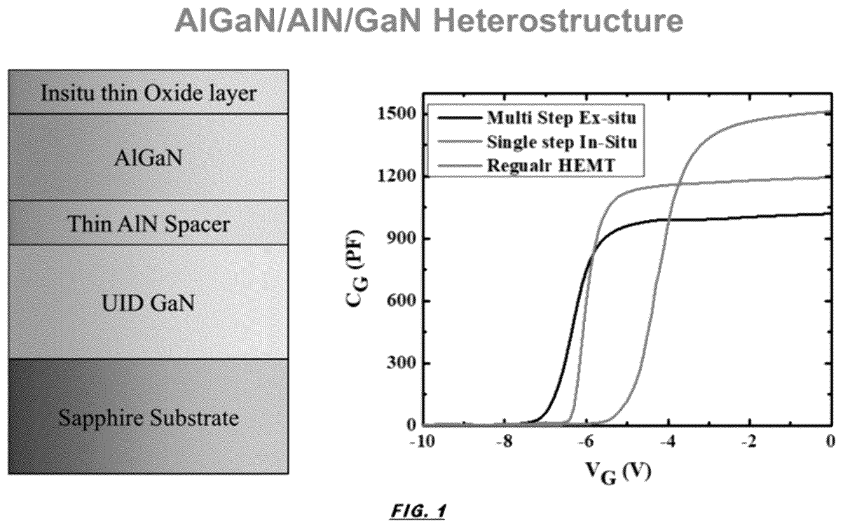

FIG. 2 shows at: a) a schematic of the epilayer structure Ga₂O₃/Al_{0.3}Ga_{0.7}N/GaN MOSHFET; b) HR-TEM image of Ga₂O₃/Al_{0.3}Ga_{0.7}N interface for in-situ; and c) ex-situ grown MOSHFET structures.

FIG. 3 shows an XRD 2θ-scan of the MOSHFET structure showing crystalline Ga₂O₃ (P phase), GaN, AlGaN, AlN, and sapphire substrate peaks.

FIG. 4 shows C-V characteristics at 1 MHz frequency of MOSHFET structures with different oxide thicknesses.

FIG. 5 shows a MOSHFET threshold voltage dispersion for in-situ and ex-situ processes with Ga₂O₃ thicknesses of 10 nm, 20 nm, and 30 nm.

FIG. 6 shows frequency-dependent C-V characteristic of a MOSHFET with 10 nm thick gate oxide at frequencies of 100 kHz, 316 kHz, and 1 MHz for a) in-situ; and b) ex-situ structure.

FIG. 7 shows Table 1—a summary of the key electrical parameters measured/calculated for HFET, in-situ and ex-situ MOSFET structures.

The figures herein are for illustrative purposes only and are not necessarily drawn to scale.

### DETAILED DESCRIPTION OF THE EXAMPLE EMBODIMENTS

Before the present disclosure is described in greater detail, it is to be understood that this disclosure is not limited to particular embodiments described, and as such may, of course, vary. It is also to be understood that the terminology used herein is for the purpose of describing particular embodiments only, and is not intended to be limiting.

Unless specifically stated, terms and phrases used in this document, and variations thereof, unless otherwise expressly stated, should be construed as open ended as opposed to limiting. Likewise, a group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise.

Furthermore, although items, elements or components of the disclosure may be described or claimed in the singular, the plural is contemplated to be within the scope thereof unless limitation to the singular is explicitly stated. The presence of broadening words and phrases such as “one or more,” “at least,” “but not limited to” or other like phrases in some instances shall not be read to mean that the narrower case is intended or required in instances where such broadening phrases may be absent.

Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, the preferred methods and materials are now described.

All publications and patents cited in this specification are cited to disclose and describe the methods and/or materials in connection with which the publications are cited. All such publications and patents are herein incorporated by references as if each individual publication or patent were specifically and individually indicated to be incorporated by reference. Such incorporation by reference is expressly limited to the methods and/or materials described in the cited publications and patents and does not extend to any lexicographical definitions from the cited publications and patents. Any lexicographical definition in the publications and patents cited that is not also expressly repeated in the instant application should not be treated as such and should not be read as defining any terms appearing in the accompanying claims. The citation of any publication is for its disclosure prior to the filing date and should not be construed as an admission that the present disclosure is not entitled to antedate such publication by virtue of prior disclosure. Further, the dates of publication provided could be different from the actual publication dates that may need to be independently confirmed.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure. Any recited method can be carried out in the order of events recited or in any other order that is logically possible.

Where a range is expressed, a further embodiment includes from the one particular value and/or to the other particular value. The recitation of numerical ranges by endpoints includes all numbers and fractions subsumed within the respective ranges, as well as the recited endpoints. Where a range of values is provided, it is understood that each intervening value, to the tenth of the unit of the lower limit unless the context clearly dictates otherwise, between the upper and lower limit of that range and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure. For example, where the stated range includes one or both of the limits, ranges excluding either or both of those included limits are also included in the disclosure, e.g. the phrase “x to y” includes the range from ‘x’ to ‘y’ as well as the range greater than ‘x’ and less than ‘y’. The range can also be expressed as an upper limit, e.g. ‘about x, y, z, or less’ and should be interpreted to include the specific ranges of ‘about x’, ‘about y’, and ‘about z’ as well as the ranges of ‘less than x’, less than y’, and ‘less than z’. Likewise, the phrase ‘about x, y, z, or greater’ should be interpreted to include the specific ranges of ‘about x’, ‘about y’, and ‘about z’ as well as the ranges of ‘greater than x’, greater than y’, and ‘greater than z’. In addition, the phrase “about ‘x’ to ‘y’”, where ‘x’ and ‘y’ are numerical values, includes “about ‘x’ to about ‘y’”.

It should be noted that ratios, concentrations, amounts, and other numerical data can be expressed herein in a range format. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. Ranges can be expressed herein as from “about” one particular value, and/or to “about” another particular value. Similarly, when values are expressed as approximations, by use of the antecedent “about,” it will be understood that the particular value forms a further aspect. For example, if the value “about 10” is disclosed, then “10” is also disclosed.

It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to 5%” should be interpreted to include not only the explicitly recited values of about 0.1% to about 5%, but also include individual values (e.g., about 1%, about 2%, about 3%, and about 4%) and the sub-ranges (e.g., about 0.5% to about 1.1%; about 5% to about 2.4%; about 0.5% to about 3.2%, and about 0.5% to about 4.4%, and other possible sub-ranges) within the indicated range.

As used herein, the singular forms “a”, “an”, and “the” include both singular and plural referents unless the context clearly dictates otherwise.

As used herein, “about,” “approximately,” “substantially,” and the like, when used in connection with a measurable variable such as a parameter, an amount, a temporal duration, and the like, are meant to encompass variations of and from the specified value including those within experimental error (which can be determined by e.g. given data set, art accepted standard, and/or with e.g. a given confidence interval (e.g. 90%, 95%, or more confidence interval from the mean), such as variations of +/−10% or less, +1-5% or less, +/−1% or less, and +/−0.1% or less of and from the specified value, insofar such variations are appropriate to perform in the disclosure. As used herein, the terms “about,” “approximate,” “at or about,” and “substantially” can mean that the amount or value in question can be the exact value or a value that provides equivalent results or effects as recited in the claims or taught herein. That is, it is understood that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In general, an amount, size, formulation, parameter or other quantity or characteristic is “about,” “approximate,” or “at or about” whether or not expressly stated to be such. It is understood that where “about,” “approximate,” or “at or about” is used before a quantitative value, the parameter also includes the specific quantitative value itself, unless specifically stated otherwise.

As used herein, “control” can refer to an alternative subject or sample used in an experiment for comparison purpose and included to minimize or distinguish the effect of variables other than an independent variable.

The term “optional” or “optionally” means that the subsequent described event, circumstance or substituent may or may not occur, and that the description includes instances where the event or circumstance occurs and instances where it does not.

As used interchangeably herein, the terms “sufficient” and “effective,” can refer to an amount (e.g. mass, volume, dosage, concentration, and/or time period) needed to achieve one or more desired and/or stated result(s). For example, a therapeutically effective amount refers to an amount needed to achieve one or more therapeutic effects.

As used herein, “tangible medium of expression” refers to a medium that is physically tangible or accessible and is not a mere abstract thought or an unrecorded spoken word. “Tangible medium of expression” includes, but is not limited to, words on a cellulosic or plastic material, or data stored in a suitable computer readable memory form. The data can be stored on a unit device, such as a flash memory or CD-ROM or on a server that can be accessed by a user via, e.g. a web interface.

As used herein, the terms “weight percent,” “wt %,” and “wt. %,” which can be used interchangeably, indicate the percent by weight of a given component based on the total weight of a composition of which it is a component, unless otherwise specified. That is, unless otherwise specified, all wt % values are based on the total weight of the composition. It should be understood that the sum of wt % values for all components in a disclosed composition or formulation are equal to 100. Alternatively, if the wt % value is based on the total weight of a subset of components in a composition, it should be understood that the sum of wt % values the specified components in the disclosed composition or formulation are equal to 100.

Various embodiments are described hereinafter. It should be noted that the specific embodiments are not intended as an exhaustive description or as a limitation to the broader aspects discussed herein. One aspect described in conjunction with a particular embodiment is not necessarily limited to that embodiment and can be practiced with any other embodiment(s). Reference throughout this specification to “one embodiment”, “an embodiment,” “an example embodiment,” means that a particular feature, structure or characteristic described in connection with the embodiment is included in at least one embodiment of the present disclosure. Thus, appearances of the phrases “in one embodiment,” “in an embodiment,” or “an example embodiment” in various places throughout this specification are not necessarily all referring to the same embodiment, but may. Furthermore, the particular features, structures or characteristics may be combined in any suitable manner, as would be apparent to a person skilled in the art from this disclosure, in one or more embodiments. Furthermore, while some embodiments described herein include some but not other features included in other embodiments, combinations of features of different embodiments are meant to be within the scope of the disclosure. For example, in the appended claims, any of the claimed embodiments can be used in any combination.

All patents, patent applications, published applications, and publications, databases, websites and other published materials cited herein are hereby incorporated by reference to the same extent as though each individual publication, published patent document, or patent application was specifically and individually indicated as being incorporated by reference. KITS

Any of the compounds and methods described herein can be presented as a combination kit. As used herein, the terms “combination kit” or “kit of parts” refers to the compounds, compositions, methods and any additional components that are used to package, sell, market, deliver, and/or provide the compounds and methods, contained therein. Such additional components include, but are not limited to, packaging, blister packages, devices, and the like. When one or more of the compounds and methods, described herein or a combination thereof (e.g., structures contained in the kit are administered simultaneously, the combination kit can contain the compounds or methods in a single combination or in separate combinations. When the compounds and methods described herein or a combination thereof and/or kit components are not provided simultaneously, the combination kit can contain each compounds and methods formulations. The separate kit components can be contained in a single package or in separate packages within the kit.

In some embodiments, the combination kit also includes instructions printed on or otherwise contained in a tangible medium of expression. The instructions can provide information regarding the content of the compounds and methods, safety information regarding the compounds and methods, information regarding the indications for use, and/or recommended applications for the compounds and methods contained therein. In some embodiments, the instructions can provide directions and protocols for performing the methods and providing the structures described herein.

Currently, the oxide deposition for GaN/AlGaN based high electron mobility transistors is done in different deposition tools, which creates additional step as well as high interfacial charge density at the oxide and barrier layer interface. Multi tool dependency increases per unit cost of the devices, whereas high interfacial charges can reduce the device performance. This innovation simplifies the fabrication process by making it a single tool dependent. In this process, the interfacial charge density is also low, compared to the multi-step process.

The passivation layers on III-Nitride-based high electron mobility transistors (HEMTs) are essential for realizing high breakdown voltage and low leakage current applications. This innovation describes a method to achieve low interfacial charge density by in-situ gate oxide-dielectric deposition on III-Nitride-based HEMT structures grown in the same reactor. The method may include the growth of the complete device structure from the substrate to the gate dielectric in a single process run without breaking the vacuum or exposing samples to air. This process enables the improved performance of the HEMT devices with gate dielectric with low interfacial charge density. The method may use techniques like metal-organic chemical vapor deposition (MOCVD), molecular beam epitaxy (MBE), a combination of these techniques, and other growth processes.

The epilayers has been developed in a single step. Initial capacitance voltage measurement shows improvement.

An in-situ metal-organic chemical vapor phase epitaxy is used to grow a complete AlGaN/GaN metal oxide semiconductor heterojunction field effect transistor (MOSHFET) structure, gated by a gallium oxide (Ga₂O₃) layer; we observed reduction in the interfacial trap density compared to its version wherein the Ga₂O₃ was grown ex-situ, all else being the same. A remarkable decrease in the interfacial charge density for in-situ MOSHFET structures in the range of 70%-88% for 10 nm to 30 nm oxide layer thickness and improvements in other electrical parameters required for high-performing devices were observed.

Gallium nitride (GaN) based heterostructure field effect transistors (HFETs) continue to play a pivotal role in high-speed, high-power, and high-temperature RF/microwave applications in harsh environments. See, H. Morkog, Handbook of nitride semiconductors and devices, Materials Properties, Physics and Growth, John Wiley & Sons (2009); and 2) H. Morkog, Nitride semiconductors and devices, Vol. 32. Springer Science & Business Media (2013). The commercial and military applications of GaN-based electronics are numerous and diverse. See, H. Morkoc, Nitride semiconductors, supra.

The fundamental problems that notably limit the performance of these devices, i.e., RF dispersion, see R. Trew, Daniel S. Green, and Jeffrey B. Shealy, IEEE Microwave magazine 10 [4], 116 (2009)., current collapse, see T. Hashizume, S. Ootomo, and H. Hasegawa, Appl. Phys. Lett. 83 [14], 2952 (2003), and knee voltage walk-out, see B. Ubochi, K. Ahmeda, and K. Kalna, ECS Journal of Solid State Science and Technology 6 [11], S3005 (2017), primarily can be attributed to the processes occurring near the gate edges. To overcome these problems, passivated HFETs or metal oxide semiconductor HFETs (MOSHFETs) have been used, see J. H. Leach and H. Morkog, in Proceedings of the IEEE 98 [7], 1127 (2010); and H. Zhou, X. Lou, K. Sutherlin, J. Summers, S. B. Kim, K. D. Chabak, R. G. Gordon, and P. D. Ye, IEEE Electron Device Letters 38 [10], 1409 (2017). In addition to the gate leakage current reduction, MOSHFETs allow larger gate voltage swings and thus the ensuing higher channel currents paving the way to superior RF performance. See, F. Husna, M. Lachab, M. Sultana, V. Adivarahan, Q. Fareed, and A. Khan, IEEE Trans. Electron Devices 59 [9], 2424 (2012).

Mitigation of the aluminum gallium nitride (AlGaN) barrier layer surface states via passivation can play a significant positive role on the overall electrical performance of AlGaN/GaN-based devices. See, J. T. Asubar, Z. Yatabe, D. Gregusova, and T. Hashizume, J. Appl. Phys. 129 [12] 121102 (2021). In a typical passivation process, the HFET structure and passivation layers are not grown in the same reactor, and thus, unavoidable air exposure and/or any other process-related steps would result in unwanted interface states, ultimately compromising the device performance. See, J. Derluyn, S. Boeykens, K. Cheng, R. Vandersmissen, J. Das, W. Ruythooren, S. Degroote, M. R. Leys, M. Germain, and G. Borghs, J. Appl. Phys. 98 [5], 054501 (2005). Chemically and thermally stable dielectric materials with high dielectric constants and large bandgaps are coveted for gate passivation layers. See, B. Lee, L. Kang, R. Nieh, W. Qi, and J. Lee, Appl. Phys. Lett. 76 [14], 1926 (2000). Previously, in-situ SiNₓ deposition has been reported on AlGaN/GaN-based devices, demonstrating that the in-situ dielectric deposition process improved the electrical performance of the device compared to the ex-situ process. See, A. Siddique, R. Ahmed, J. Anderson, M. Nazari, L. Yates, S. Graham, M. Holtz, and E. L. Piner, ACS Appl. Electronic Mat. 1 [8], 1387 (2019); H. Jiang, C. Liu, Y. Chen, X. Lu, C. W. Tang, and K. M. Lau, IEEE Trans. Electron Devices 64 [3], 832 (2017); and M. Germain, K. Cheng, J. Derluyn, S. Degroote, J. Das, A. Lorenz, D. Marcon, M. Van Hove, M. Leys, and G. Borghs, physica status solidi (c) 5 [6], 2010 (2008). Typically, SiNₓ dielectric constant (7.4) is low, with a moderate bandgap ranging from 2.9 to 5.1 eV based on the stoichiometric ratio. See, A. Siddique, supra. Usually, oxide-based dielectric material systems have a wide choice of dielectric constants and bandgaps. See, T. Hashizume, K. Nishiguchi, S. Kaneki, J. Kuzmik, and Z. Yatabe, Mater. Sci. Semicond. Process, 78, 85 (2018). As in the case of nitride-based dielectric systems, it follows that inclusion of oxide-based dielectrics, particularly in-situ varieties, should improve the overall metal oxide semiconductor (MOS) based device performance. However, integrating III-Nitride and III-oxide precursors in the same reactor brings about process-related challenges. The typical III-nitride-based growth processes use hydrogen as a carrier gas, where the inclusion of oxygen (O₂) precursor may be catastrophic. See, M. A. A. Clyne and B. A. Thrush, Nature, 189 [4759], 135 (1961). The commonly used nitrogen precursor ammonia (NH₃) is highly reactive with oxygen precursors, which may lead to water formation inside the reactor. See, E. A. Albers, K. Hoyermann, H. G. Wagner, and J. Wolfrum, Symposium (International) on Combustion, 13 [1], 765 (1971). Thus, the integration of nitride and oxide-based technology in the same reactor is challenging.

In this disclosure, we provide in-situ oxide dielectric, gallium oxide (Ga₂O₃) with a dielectric constant of 10.6 and bandgap of 4.9 eV, by metal-organic chemical vapor deposition (MOCVD) on an AlGaN/GaN-based HFET structure to create a complete in-situ MOSHFET structure in a single process step, starting from the sapphire substrate and without breaking vacuum. Nitrogen was used as a carrier gas to avoid the reaction between high-purity oxygen instead of the typical hydrogen gas. For comparison, we created an ex-situ MOSHFET structure where the Ga₂O₃ layers were grown on the HFET structure albeit after its exposure to air. The thicknesses of the oxide and other layers for the in-situ and ex-situ structures were kept the same. The properties related to the oxide and AlGaN layers were studied, and a comparison was made based on different oxide charges and density of interface traps (Dᵢₜ) along with other electrical parameters. We also investigated the root cause for threshold voltage (Vₜₕ) shift using a thickness-dependent model, see M. Tapajna and J. Kuzmik, Appl. Phys. Lett., 100 [11] 113509 (2012) and Y. Zhang, M. Sun, S. J. Joglekar, T. Fujishima, and T. Palacios, Appl. Phys. Lett. 103 [3], 033524 (2013)., correlating the theory and our experimental data.

The epilayer structures for this study were deposited on a sapphire substrate in a custom built vertical metal-organic chemical vapor deposition (MOCVD) system, with nitrogen (N₂) as carrier gas. Trimethylaluminum (TMAl), ammonia (NH₃), and ultra-high purity oxygen (O₂) were used as aluminum (Al), nitrogen, and oxygen precursors. The choice of triethylgallium (TEGa) as gallium (Ga) precursor is motivated by previous reports that, the use of TEGa can reduce GaN yellow band defects in the nitrogen carrier gas approach. See, T. Hubdcek, A. Hospodkovi, K. Kuldovi, M. Slavicki Zikovi, J. Pangric, J. Cifek, M. O. Liedke, M. Butterilng, A. Wagner, P. Hubik, and E. Hulicius, J. Cryst. Growth 531, 125383 (2020). The epilayers of the MOSFET structure consist of a thin 150 nm aluminum nitride (AlN) layer. See, S. Hasan, A. Mamun, K. Hussain, M. Gaevski, I. Ahmad, and A. Khan, J. Mater. Res. 36 [21], 4360 (2021; and S. Hasan, M. U. Jewel, S. G. Karakalos, M. Gaevski, and I. Ahmad, Coatings 12 [7], 924 (2022)., a 500 nm thick gallium nitride (GaN) layer grown using a V/III ratio of 8000 at a temperature of 960° C., a 2 nm AlN spacer, and a 25 nm thick aluminum gallium nitride (Al_{0.3}Ga_{0.7}N) barrier layer grown using a V/III ratio of 5000 at a temperature of 1020° C. at 100 Torr chamber pressure, and finally, a set of 10 nm, 20 nm, and 30 nm thick □-Ga₂O₃ layers as gate dielectrics were grown at 700° C., 50 Torr chamber pressure, and a VI/III ratio of ˜900. S. Hasan, M. Uddin Jewel, S. R. Crittenden, D. Lee, V. Avrutin, Ü. Özgür, H. Morkoç, and I. Ahmad, Crystals, 13 [2], 231 (2023). For the in-situ growth process the system was nitrogen purged for 30 min prior to growing Ga₂O₃ in order to avoid an overlap of oxygen and hydrogen species at 50 Torr. A Rigaku Miniflex II Desktop X-ray diffractometer with Cu-Kα1 x-ray source (λ=1.5406 Å) operated at 30 mA current and 15 kV voltage was used to evaluate the structural properties of the epilayers. The capacitance-voltage (C-V) measurements were performed using a mercury probe controller (Materials Development Corporation, CA, USA) model 802B connected with an HP 4284A Precision LCR Meter capable of measuring the impedance as a function of frequency. The gate diameter of the mercury probe was 797 m with 0.1 pF stray capacitance.

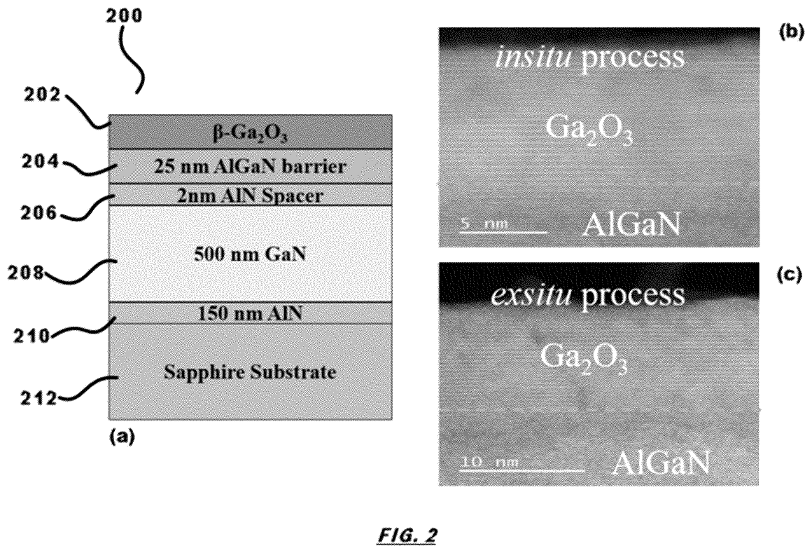

FIG. 2 shows the device structures investigated, where FIG. 2 at (a) exhibits the schematic of the MOSHFET structure 200. In one embodiment, MOSHFET structure 200 may include an uppermost β-Ga₂O₃ layer 202, above an AlGaN barrier layer 204, this above a AlN spacer layer 206, above a GaN layer 208, over a second AlN layer 210 affixed to sapphire substrate 212. FIG. 2 at (b) and (c) show the high-resolution transmission electron microscopy (HR-TEM) images of the barrier AlGaN and Ga₂O₃ interface for a 10 nm thick Ga₂O₃ MOSHFET structure with oxide layer grown by in-situ and ex-situ processes, respectively. The interfaces are marked by dashed lines for clarity. We observe no apparent defects or imperfections, such as dislocations, stacking faults, or grain boundaries, present at the interface in both in-situ and ex-situ processes. From the atomic arrangement in the HR-TEM image, we can infer that, the transition from AlGaN to Ga₂O₃ did not create visible defects which can impact the electrical property; to confirm this, a detailed study will be needed, which is beyond the scope of this paper.

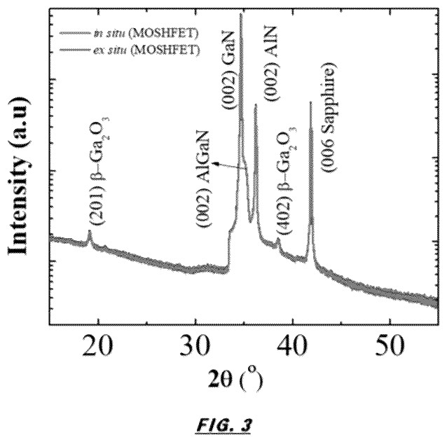

To understand the crystal structure of the whole MOSHFET structure and to identify the presence of any other Ga₂O₃ phase, XRD 2q scans were performed, as shown in FIG. 3. Due to the notably different lattice structures of AlGaN and b-Ga₂O₃, the stable phase monoclinic β-Ga₂O₃ grows in the [201] direction on (0001) oriented wurtzite AlGaN. See, M. U. Jewel, S. Hasan, S. R. Crittenden, V. Avrutin, U. Ozgur, H. Morkog, and I. Ahmad, physica status solidi (a), (2023). Here, we observed no change in peak positions of the in-situ and ex-situ MOSHFET structures. The peaks at 18.8° and 38.2° are related to the (2̅01) and (4̅02) Ga₂O₃ of the β phase. See, S. Ghose, S. Rahman, L. Hong, J. S. Rojas-Ramirez, H. Jin, K. Park, R. Klie, and R. Droopad, J. of Appl. Phys. 122 [9], 095302 (2017). The peak at 34.5° and the adjacent higher angle shoulder are consistent with the (002) reflection from the GaN channel and AlGaN barrier layers, respectively. See, M. A. Moram and M. E. Vickers, Reports on prog. in phys., 72 [3], 036502 (2009). Note that the GaN channel layer was grown on 0.15 μm thick AlN and thus the peak at 36.10 is due to the (002) AlN reflection. The peaks at 20.4° and 41.6° correspond to the (003) and (006) sapphire reflections, respectively. See S. Ghose, supra. Guided by the XRD data and HR-TEM images, we can conclude that both the Ga₂O₃ and AlGaN were crystalline in both types of (in-situ and ex-situ) MOSHFETs structures. Despite the change in orientation of Ga₂O₃ to fit the lattice structure on which it is grown AlGaN, there was no visible structural defect formation at the interface of these two materials.

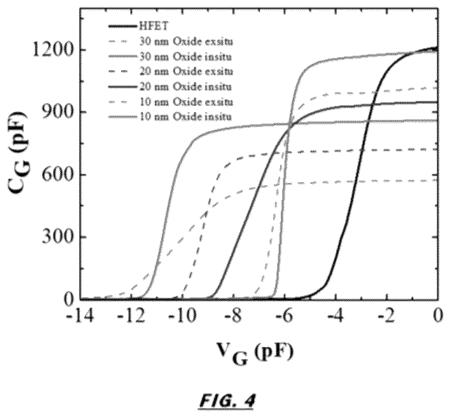

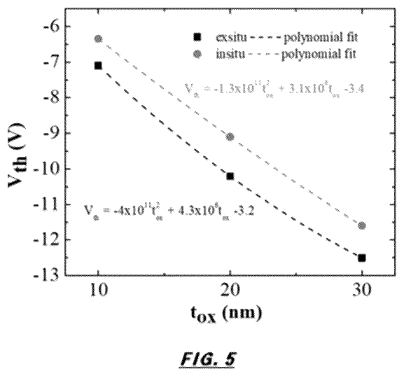

FIG. 4 shows the capacitance-voltage (C-V) measurement for the MOSHFET structures investigated. The threshold voltage shifts, and capacitance in the accumulation region decreases when a β-Ga₂O₃ is incorporated as a passivation layer on top of an Al_{0.3}Ga_{0.7}N/GaN HFET structure. Typically, with the increase of dielectric layer thickness, and decrease of dielectric constant, the threshold voltage shift tends at higher values. See, S Hasan, Crystals, supra. The addition of an oxide layer adds a capacitance in series with the overall capacitance described as

$$\frac{1}{{C}_{G}} = \frac{1}{{C}_{b}} + \frac{1}{{C}_{o x}} ,$$

where C_{b} is the Al_{0.3}Ga_{0.7}N barrier layer capacitance, Cₒₓ is the capacitance Ga₂O₃ layer, C_{G} is the total gate capacitance; thus, the capacitance in accumulation region of C-V curve decreases with the increase of the dielectric layer thickness. See Id. From FIG. 4, one can also discern that for similar oxide thickness, the threshold voltage shift is smaller associated with the in-situ process as compared to the ex-situ process. Id. The 2-dimensional electron gas (2DEG) carrier concentration (nₛ) for all three samples was measured by C-V, and the 2DEG carrier concentrations in ex-situ and in-situ processes were found to be in the range of 1.18×10¹³ cm⁻² to 1.42×10¹³ cm⁻², respectively, for different thickness samples. The origin of the shift in threshold voltage can be attributed to the gate-to-channel distance and to the bulk oxide charge density (n_{ox,bulk}), and the interface oxide charge density (n_{ox,inf}), and can be visualized using equation 1 below. See, M. Tapajana, supra; S Hasan, Crystal, supra; and S. Mollah, K. Hussain, A. Mamun, D. Alam, M. Chandrashekhar, G. Simin, and A. Khan, Appl. Phys. Express 15 [10], 104001 (2022).

$${V}_{th} = {φ}_{b} - {φ}_{f} - Δ {E}_{C} - \frac{q {t}_{ox}^{2}}{2 {ε}_{ox}} {n}_{ox . bulk} - \frac{q {t}_{ox}}{{ε}_{ox}} {n}_{ox . intf} - q ( \frac{{t}_{ox}}{{ε}_{ox}} + \frac{{t}_{b}}{{ε}_{b}} ) \qquad ( 1 )$$

Where φ_{b} is the metal-barrier height and taken as 4.3 eV as we are using a mercury probe as gate metal. The term ΔE_{C} is the conduction band discontinuity at the oxide AlGaN interface. (pf is the energy difference between the conduction band and Fermi energy level in the GaN, and tₒₓ and t_{b} are the oxide and barrier layer thicknesses. The impact of in-situ passivation and the dependence of Vₜₕ on the ex-situ and in-situ process need an analytical model to decipher any correlation between the process and the electrostatic centric parameters associated with the two different processes. We used the oxide thickness-dependent C-V measurements to gauge the influence of different oxide charges on the Vₜₕ shift. Based on equation (1), Vₜₕ can be represented as 2^{nd} order polynomial function, as shown in FIG. 5, through a polynomial fitting process of the thickness-dependent Vₜₕ dispersion, n_{ox,bulk} and n_{ox,intf} can be calculated. Note these values are an average over the area of the capacitor and there can be another term, such as N_{d,surf}, usually used to explain the formation of a 2DEG at the barrier and channel layer interface. The said charge (N_{d,surf}) is formed during the growth process and follows the charge neutrality condition to minimize the free energy. See, M. Tapajana, supra. The interface charge depends on the oxide layer thickness and usually compensated by the formation of 2DEG and can be excluded from the calculation. See, Id. From the fit, the value of n_{ox,bulk} for the ex-situ MOSHFET samples was found to be +8.9×10²⁰ cm⁻³, whereas the value for the same for the in-situ sample was +1.5×10²⁰ cm⁻³, which is smaller compared to the ex-situ process. The value of n_{ox,intf} for the ex-situ and in-situ grown MOSHFET structures were found to be −2.5×10¹⁵ cm⁻² and −1.8×10⁵ cm⁻², indicating a slightly lower value for in-situ grown MOSHFET structure. It is evident that both n_{ox,bulk} and n_{ox,intf} for the in-situ MOSHFET structure are lower compared to the ex-situ MOSHFET structure and can contribute to the Vₜₕ shift.

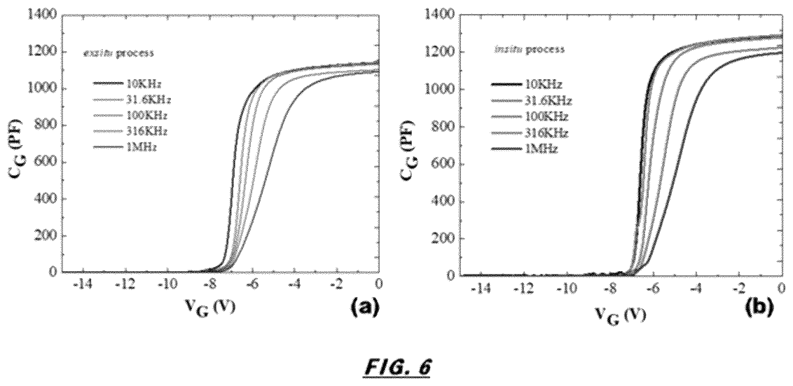

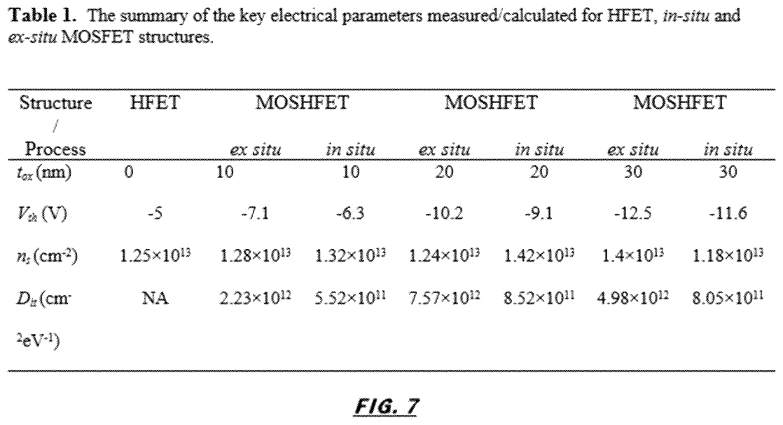

To further identify the dominating parameters responsible for the observed Vₜₕ shift, we calculated the density of interfacial trap states (Dᵢₜ). The frequency-dependent through Hi-Lo method, and the associated equation (2), was used to calculate the interfacial trap density (Dᵢₜ) in both in-situ and ex-situ grown MOSHFET structures. See, D. K. Schroder, in Semiconductor Material and Device Characterization, John Wiley & Sons, Inc. (2005). At low frequencies, the trap states get sufficient time to respond to voltage modulation, leading to higher capacitance, whereas, at high frequencies, they cannot respond, leading to a low capacitance value. In this methodology, the interfacial trapped state density is given as (See Id.):

$${D}_{it} ( {V}_{G} ) = \frac{{C}_{ox}}{q} ( \frac{{C}_{LF}}{{C}_{ox} - {C}_{LF}} - \frac{{C}_{H F}}{{C}_{ox} - {C}_{H F}} ) , \qquad ( 2 )$$

where Cₒₓ is the capacitance of the dielectric oxide layer, which can be calculated using the parallel plate capacitor formula, q is the unit elementary charge, C_{LF} is the MOSHFET low-frequency capacitance value and C_{HF} is the MOSHFET high-frequency capacitance value. FIG. 6 shows the frequency-dependent capacitance data for both in-situ and ex-situ MOSHFET structures for a common 10 nm Ga₂O₃ layer. The value of Dᵢₜ for ex-situ MOSHFET structure is ˜10¹² cm⁻² eV⁻¹, which is reduced to ˜10¹¹ cm⁻² eV⁻¹ for in-situ MOSFET structure (exact values are mentioned in Table 1, see FIG. 7), which is remarkable. This reduction (˜80% reduction) of the interfacial trap density is most likely the main contributing factor for Vₜₕ improvement as a result of the in-situ process. Any improvement in Vₜₕ is bodes very well in our quest to improve device performance. FIG. 7 shows Table 1, a summary of the key electrical parameters measured/calculated for HFET, in-situ and ex-situ MOSFET structures.

In summary, we have demonstrated a process for in-situ oxide dielectric deposition in the same reactor, integrating III-Nitride and III-Oxide technology using N₂ as carrier gas that results in a lower density of interface traps (charges). No significant crystal quality difference is observed in comparing both processes by using TEM and XRD was notable. Compared to ex-situ MOSHFET structures, the threshold voltage is improved by ˜10% in the case of the in-situ sample, which is a critical scaling factor for power efficiency. There is the output power efficiency and there is ability on the input side to be able to utilize the output power that the device can deliver. Based on the analytical model, we found that all the key parameters, namely n_{ox,bulk}, n_{ox,intf}, and Dᵢₜ, reduced for the in-situ MOSHFET variety. It should be stressed that reduction in Dᵢₜ by an order of magnitude with the in-situ approach seems to be the main reason for threshold voltage improvement.

Various modifications and variations of the described methods, compositions, and kits of the disclosure will be apparent to those skilled in the art without departing from the scope and spirit of the disclosure. Although the disclosure has been described in connection with specific embodiments, it will be understood that it is capable of further modifications and that the disclosure as claimed should not be unduly limited to such specific embodiments. Indeed, various modifications of the described modes for carrying out the disclosure that are obvious to those skilled in the art are intended to be within the scope of the disclosure. This application is intended to cover any variations, uses, or adaptations of the disclosure following, in general, the principles of the disclosure and including such departures from the present disclosure come within known customary practice within the art to which the disclosure pertains and may be applied to the essential features herein before set forth.

What is claimed is:

1. A method for forming a metal oxide semiconductor heterojunction field effect transistor comprising:
employing a single process step in-situ metal-organic chemical vapor phase epitaxy using nitrogen as a carrier gas to provide for vertical metal-organic chemical vapor deposition;
wherein at least one ultra-wide-bandgap semiconductor is deposited via metal-organic chemical vapor deposition onto at least one high-electron-mobility transistor heterostructure atop at least one sapphire substrate to form at least one in-situ metal oxide semiconductor heterojunction field effect transistor.

2. The method of claim 1, further comprising forming the at least one in-situ metal oxide semiconductor heterojunction field effect transistor having a decrease in interfacial charge density for the in-situ formed metal oxide semiconductor heterojunction field effect transistor in a range of 70%-88% for a 10 nm to 30 nm oxide layer thickness as compared to an ex-situ formed metal oxide semiconductor heterojunction field effect transistor.

3. The method of claim 1, further comprising forming the at least one in-situ metal oxide semiconductor heterojunction field effect transistor having reduction in interfacial trap density as compared to an ex-situ formed metal oxide semiconductor heterojunction field effect transistor.

4. The method of claim 1, further comprising forming the at least one in-situ metal oxide semiconductor heterojunction field effect transistor having a dielectric constant of 10.6 and bandgap of 4.9 eV.

5. The method of claim 1, wherein the ultra-wide-bandgap semiconductor comprises gallium oxide.

6. The method of claim 1, wherein the at least one high-electron-mobility transistor heterostructure comprises an AlGaN/GaN-based heterostructure.

7. The method of claim 1, wherein the at least one in-situ metal oxide semiconductor heterojunction field effect transistor is formed to comprise, an upper most β-Ga₂O₃ layer above a AlGaN barrier layer above an AlN spacer layer above a GaN layer over a second AlN layer atop the at least one sapphire substrate.

8. The method of claim 7, wherein trimethylaluminum, ammonia, and ultra-high purity oxygen are used as aluminum, nitrogen, and oxygen precursors.

9. The method of claim 1, wherein the method is performed in a single reactor.

10. An improved metal oxide semiconductor heterojunction field effect transistor comprising:
at least one uppermost β-Ga₂O₃ layer formed above a AlGaN barrier layer that is formed above an AlN spacer layer formed above a GaN layer formed over a second AlN layer formed atop at least one sapphire substrate;
wherein the metal oxide semiconductor heterojunction field effect transistor is formed in situ in a single reactor.

11. The improved metal oxide semiconductor heterojunction field effect transistor of claim 10, wherein the in-situ metal oxide semiconductor heterojunction field effect transistor has a decrease in interfacial charge density for the in-situ formed metal oxide semiconductor heterojunction field effect transistor in a range of 70%-88% for a 10 nm to 30 nm oxide layer thickness as compared to an ex-situ formed metal oxide semiconductor heterojunction field effect transistor.

12. The improved metal oxide semiconductor heterojunction field effect transistor of claim 10, wherein the at least one in-situ formed metal oxide semiconductor heterojunction field effect transistor has a reduction in interfacial trap density as compared to Ga₂O₃ grown ex-situ.

13. The improved metal oxide semiconductor heterojunction field effect transistor of claim 10, wherein the at least one in-situ formed metal oxide semiconductor heterojunction field effect transistor has a dielectric constant of 10.6 and bandgap of 4.9 eV.

14. The improved metal oxide semiconductor heterojunction field effect transistor of claim 10, wherein the ultra-wide-bandgap semiconductor comprises gallium oxide.

15. The improved metal oxide semiconductor heterojunction field effect transistor of claim 10, wherein the at least one high-electron-mobility transistor heterostructure comprises an AlGaN/GaN-based heterostructure.

16. The improved metal oxide semiconductor heterojunction field effect transistor of claim 10, wherein the in-situ metal oxide semiconductor heterojunction field effect transistor comprises an upper most β-Ga₂O₃ layer above a AlGaN barrier layer above an AlN spacer layer above a GaN layer over a second AlN layer atop the at least one sapphire substrate.

17. The improved metal oxide semiconductor heterojunction field effect transistor of claim 16, wherein trimethylaluminum, ammonia, and ultra-high purity oxygen are used as aluminum, nitrogen, and oxygen precursors.
